(19) United States
(12) Patent Application Publication
(10) Pub. No.: US 2007/0128559 A1
(43) Pub. Date: Jun. 7, 2007

(54) MATERIAL FOR FORMING FINE PATTERN, METHOD OF FORMING FINE PATTERN, METHOD OF MANUFACTURING ELECTRONIC DEVICE USING THE SAME, AND ELECTRONIC DEVICE MANUFACTURED FROM THE SAME

(75) Inventors: Takeo ISHIBASHI, Chiyoda-ku (JP); Tetsuro Hanawa, Chiyoda-ku (JP); Mamoru Terai, Chiyoda-ku (JP); Teruhiko Kumada, Chiyoda-ku (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/561,168

(22) Filed: Nov. 17, 2006

(30) Foreign Application Priority Data
Nov. 18, 2005 (JP) 2005-334097

(51) Int. Cl. G03F 7/00

(52) U.S. Cl. 430/330

(57) ABSTRACT

A raw material of a cover layer as a material for forming a fine pattern is applied as to cover a resist pattern. Then, a component in the cover layer permeates into the resist pattern. Thereby, a mixed layer having a lower softening point than that of the resist pattern is formed. Then, a heat treatment is performed at a temperature lower than the softening point of the resist pattern and higher than that of the mixed layer. Thereby, the mixed layer is softened and a width of the mixed layer becomes large. As a result, a space of the resist pattern is narrowed. Therefore, a fine pattern is formed having a smaller size than the size limit due to the exposure wavelength.

### BACKGROUND OF THE INVENTION

1. Field of the Invention

The present invention relates to a method of forming a fine pattern used in a method of manufacturing an electronic device, and the like.

2. Description of the Background Art

With the high integration of electronic devices, a space between patterns such as wiring required in a manufacturing process has become extremely small. Generally, a fine pattern is formed by etching an underlayer using a resist pattern formed with a lithography technique as a mask. Therefore, the lithography technique is very important in a method of forming a fine pattern. The lithography technique includes a step of applying resist, a step of positioning a reticle (mask), a step of exposing, and a step of developing. Therefore, miniaturization of the pattern is limited by exposure wavelength. In the manufacturing of an electronic device, the pattern has already been miniaturized to the size limit due to the exposure wavelength.

In order to go beyond the limit of resolution due to the above-described exposure wavelength, research and development of the technology as follows have been performed.

For example, Japanese Patent Laying-Open No. 05-166717 discloses the technology as follows. First, an opening pattern is formed in a resist for forming a pattern on a substrate. Next, a resist for generating a mixing layer is applied on the substrate as to cover the entire resist for forming a pattern. Then, the substrate is baked, a part of the resist for generating a mixing layer contacting to the resist for forming a pattern changes, and the mixing layer is formed along the side faces and the top face of the resist for forming a pattern. Further, the part of the above-described resist for generating a mixing layer which did not become the mixing layer is removed. As a result, an opening pattern is formed having a width smaller by dimension of the mixing layer.

According to the above-described method, a fine pattern can be formed relatively easily using the mixing layer. However, the problem occurs that a resist for generating a mixing layer appropriate to a resist for forming a pattern has to be always used.

On the other hand, Japanese Patent Laying-Open No. 07-045510 discloses a method of making the space of the pattern small by liquidizing a resist pattern by heat treatment and so forth. In this method, first, a resist pattern is formed on a substrate. Next, a heat treatment is performed at the temperature of the softening point of the resist pattern or more, and the cross-sectional shape of the resist pattern changes. Hereby, the space of the pattern becomes small.

According to this method, the space between line patterns, the space of spacing patterns, and the space as a diameter of a hole pattern can be made small using the existing resist material in the thermal process. However, because the entire resist pattern after development is heat-treated and liquidized at the temperature of its softening point or more, it is difficult to strictly control the amount of change in the dimension per unit temperature. Especially, in the case that a resist material having a high softening point is used, there is a problem that it is very difficult to strictly control the external shape of the resist pattern because the amount of change in the dimension of the entire resist pattern per unit temperature is large.

For example, Japanese Patent Laying-Open No. 2003-202679 discloses a method in which the above-described method is developed as follows. First, a resist pattern is formed on a substrate. Next, a cover layer is formed on the substrate that thermally shrinks at a lower temperature than the softening point of the resist pattern. Then, a heat treatment is performed at the above-described temperature. In this heat treatment, the resist pattern is pulled outwards by the shrinkage of the cover layer, and the space of the resist patterns becomes small. Further, the same technology as in the above-described document is disclosed in Japanese Patent Laying-Open No. 2004-037571 and Japanese Patent Laying-Open No. 2004-037570.

However, in this method, it is difficult to control the external shape of the resist pattern because the amount of thermal shrinkage depends on the thickness of the cover layer. Further, the amount of thermal shrinkage changes depending on the layout of the resist pattern. Therefore, there is a problem that it is difficult to uniformly change the external shape of the resist pattern in the inner direction on the wafer surface.

Further, for example, with the technology disclosed in Japanese Patent Laying-Open No. 10-073927 and Japanese Patent Laying-Open No. 05-241348, it is possible to form a fine pattern. According to the technology disclosed in these documents, first, a resist pattern is formed on a substrate. Then, a cover layer consisting of a water-soluble resin having an acid cross-linking property is formed as to cover the surfaces of the substrate and the resist pattern. Next, a cross-linked layer is formed in the cover layer utilizing the acid diffusing from the resist pattern to the cover layer by heating. Then, a non cross-linked part of the cover layer, that is a part excluding the cross-linked layer, is removed. As a result, a resist pattern is formed having a size space of the size limit or less due to the limit of the resolution of the exposure wavelength. However, with the technologies described in these documents, it is difficult to control the dimension of the space of the resist pattern.

### SUMMARY OF THE INVENTION

The present invention is made considering the above-described problem, and its objective is to provide a material for forming a fine pattern used to form a fine pattern having a smaller size than the size limit due to the exposure wavelength, a method of forming a fine pattern using the same, a method of manufacturing an electronic device using the same, and an electronic device manufactured with the same.

The material for forming a fine pattern in the present invention is applied on the resist pattern as a cover layer covering a resist pattern on a substrate. A component of the material for forming a fine pattern permeates into the resist pattern. Thereby, a mixed layer having a lower softening point than the softening point of the resist pattern is formed. Then, a heat treatment is performed at a temperature lower than the softening point of the resist pattern and higher than that of the mixed layer. Thereby, the mixed layer is softened. As a result, the space of the resist pattern is narrowed.

Because the space of the resist patterns can be narrowed smaller than the size limit due to the exposure wavelength with the above-described material for forming a fine pattern, a fine pattern smaller than the size limit due to the exposure wavelength can be formed.

Further, the material for forming a fine pattern in the present invention is prepared as follows. First, a resist pattern is formed on a substrate. Next, a cover layer covering the resist pattern is formed. Then, a component in the cover layer permeates into the resist pattern. Thereby, a mixed layer having a softening point lower than that of the resist pattern is formed. Next, by performing a heat treatment at a temperature lower than the softening point of the resist pattern and higher than that of the mixed layer, the mixed layer is softened. As a result, the space of the resist pattern in narrowed. Furthermore, the cover layer is removed.

Further, the electronic device in the present invention is manufactured by forming the above-described material for forming a fine pattern on the material to be etched and etching the material to be etched using the material for forming a fine pattern as a mask.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1, FIG. 2 and FIG. 3 are figures showing a resist mask of a hole pattern, a line pattern, and a space pattern respectively formed with a method for forming a fine pattern in an embodiment.

FIG. 4 to FIG. 9 are figures explaining the method for forming a fine pattern in the embodiment.

FIG. 10 is a figure explaining a method of manufacturing an electronic device by etching a material to be etched using the material for forming a fine pattern in the embodiment.

FIG. 11 is a figure explaining another method for forming a fine pattern in the embodiment.

### DESCRIPTION OF THE PREFERRED EMBODIMENTS

Referring to the figures, a material for forming a fine pattern, a method of forming a fine pattern, a method of manufacturing an electronic device using the same, and an electronic device manufactured with the same are explained in detail.

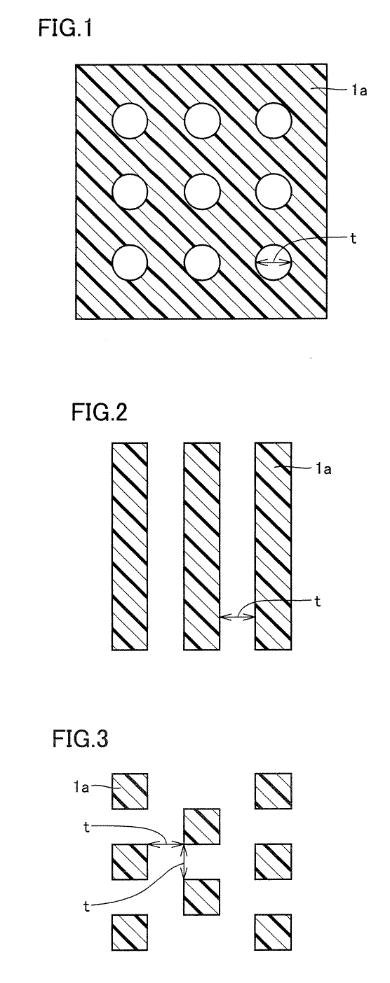

The material for forming a fine pattern in the embodiment is a resist pattern 1a having a hole pattern shown in FIG. 1, a line pattern shown in FIG. 2, and a space pattern shown in FIG. 3. Further, the characteristic of resist pattern 1a in the embodiment is that the size of the space shown as a reference letter “t” in FIG. 1 to FIG. 3 is smaller that that of the conventional space. An electronic device having a fine pattern is manufactured using these resist patterns 1a shown in FIG. 1 to FIG. 3.

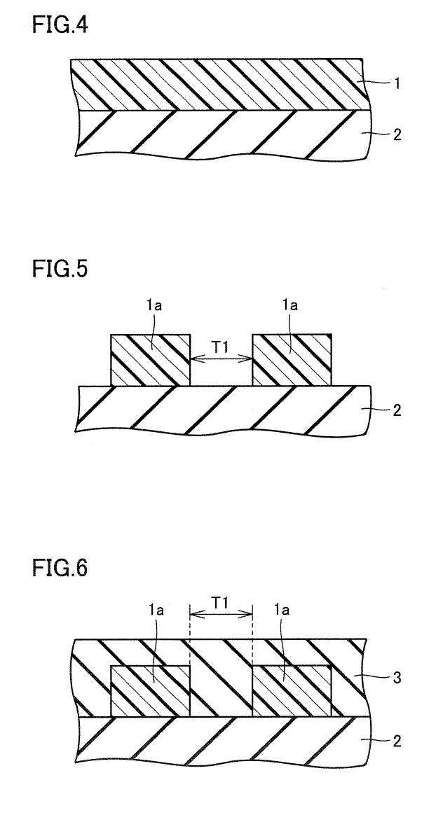

In a method of manufacturing the electronic device, first, as shown in FIG. 4, a resist film 1 is formed on an insulating layer 2 as a material to be etched at the top or the upper part of a semiconductor substrate (not shown in the figures). Next, as shown in FIG. 5, resist pattern 1a is formed having a space T1 on insulating layer 2 using the lithography technique. Next, as shown in FIG. 6, a cover layer 3 covering resist pattern 1a is applied. The raw material of cover layer 3 to be applied is a material for forming a fine pattern in the present invention. Then, a component in cover layer 3 permeates into resist pattern 1a. Because of this, as shown in FIG. 7, a mixed layer 4 having a lower softening point than that of resist pattern 1a is formed along the surface of resist pattern 1a. At this point, a space T2 of resist pattern 1a with mixed layer 4 is slightly narrower than space T1 due to the permeation of the component in cover layer 3 into resist pattern 1a. Next, as shown in FIG. 8, cover layer 3 is removed.

Next, a heat treatment is performed at a temperature lower than the softening point of resist pattern 1a, and mixed layer 4 is softened. As a result, as shown in FIG. 9, a mixed layer 4a is formed along the surface of resist pattern 1a. The width of mixed layer 4a in the direction along the main surface 2 of insulating layer 2 is larger than that of mixed layer 4. More specifically, by melting mixed layer 4, the thickness of mixed layer 4 on the upper surface of resist pattern 1a becomes small, and the thickness of mixed layer 4 on the side faces of resist pattern 1a becomes large.

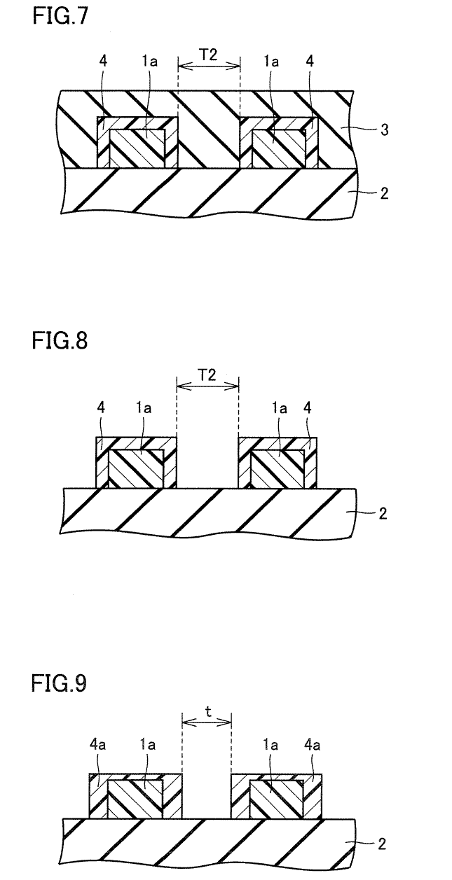

Because of this, a space t is formed in the resist pattern with the above-described mixed layer 4. Space t is narrower than space T1 and T2 (T1>T2>t). Then, as shown in FIG. 10, insulating layer 2 is etched using resist pattern 1a with the mixed layer 4 after softening as a mask, and a hole 2a is formed. Hole 2a is filled with a conductive material, and a conductive layer 10 located at the lower side of insulating layer 2 and the conductive material are connected.

Because of this, hole 2a is miniaturized more than the conventional hole. Further, when such a method for forming a fine pattern is used generally in a method of manufacturing an electronic device, the entire electronic device is capable of being miniaturized.

Furthermore, in the embodiment, a step of forming mixed layer 4a by softening mixed layer 4 shown in FIG. 9 is performed after a step of removing cover layer 3 shown in FIG. 8. That is, a step of forming mixed layer 4 right after a component in cover layer 3 permeates into resist pattern 1a (refer to FIG. 7), and a step of forming mixed layer 4a by softening mixed layer 4 (refer to FIG. 9), are performed in a heat treatment step with two different kinds of treatment conditions. According to this manufacturing method, because mixed layer 4 can be softened without cover layer 3, the mixed layer is easily softened.

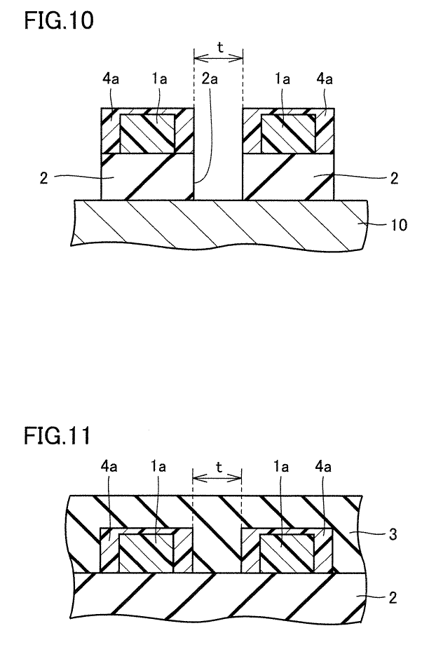

However, before the step of removing cover layer 3, that is in the state that resist pattern 1a with mixed layer 4 shown in FIG. 7 is covered with cover layer 3, mixed layer 4a may be formed between cover layer 3 and resist pattern 1a as shown in FIG. 11 by a heat treatment. In this case, the step of forming the mixed layer right after a component in cover layer 3 permeates into resist pattern 1a and the step of forming mixed layer 4a by softening the mixed layer are performed in a series of heat treatment steps. Furthermore, in the series of heat treatments, the heat treatment condition (temperature, pressure, and so forth) when the mixed layer right after a component in cover layer 3 permeates into resist pattern 1a is formed and the heat treatment condition when mixed layer 4a is formed by softening the mixed layer are same. According to this manufacturing method, because there is no need to change the heat treatment condition, the manufacturing process is simplified.

According to the above-described method of manufacturing an electronic device, space T1 of resist pattern 1a formed in the size limit due to the wavelength of the light used in the lithography technique can be made to be smaller. Further, according to the method of forming a fine pattern in the embodiment, because only the mixed layer formed along the surface of resist pattern 1a is softened, compared to the conventional method in which the entire resist pattern is softened, the change in the shape of the entire resist pattern in the heat treatment is easily controlled and space T1 of the resist pattern can be narrowed almost uniformly.

Further, a material having a resin as a main component which dissolves in a solvent that resist pattern 1a does not dissolve in is used as the above-described cover layer 3, that is a material for forming a fine pattern in the present invention. For example, at least one kind of material as a resin selected from alkylene glycol polymers, cellulose derivatives, vinyl derivatives, acrylic derivatives, urea polymers, epoxy polymers, melamine polymers, nylon polymers, and styrene polymers is used. Further, a monomer or an oligomer of amine compounds, or a monomer or an oligomer of amide compounds may be added to the solvent. Further, a permeable solvent having a lone pair may be added to the solvent. Furthermore, a surfactant may be added to the solvent.

The material for forming a fine pattern of the above-described embodiment, the method of forming a fine pattern, the method of manufacturing an electronic device using the same, and the electronic device manufactured with the same are explained in detail below.

First the method of forming a resist pattern in the present invention is explained more specifically in Examples 1 to 4. Furthermore, a resist pattern shown in FIG. 1 to FIG. 3 is formed in Examples 1 to 4.

### EXAMPLE 1

The resist material in this example is an i-line resist used for an exposure apparatus emitting light of about 365 nm wavelength; it includes a novolak resin and naphthoquinone diazito as a solute, and includes ethyl lactate and propylene glycol monoethyl acetate.

First, a resist material is dropped onto insulating layer 2 as a material to be etched and rotationally applied (spin coating) on insulating layer 2. Next, a pre-bake of the resist material is performed at a temperature of 85° C. for 70 seconds. Thereby, the solvent in the resist material is vaporized. As a result, as shown in FIG. 4, resist film 1 is formed on insulating layer 2. Furthermore, the film thickness of resist film 1 is about 1.0 μm.

Next, resist film 1 is exposed. At this time, an i-line reduction projection exposure apparatus is used as an exposure apparatus. Further, a reticle (photo mask) corresponding to the resist pattern shown in FIG. 1 to FIG. 3 is used. Next, a heat treatment at a temperature of 120° C. for 70 seconds after the exposure, that is PEB (Post Exposure Bake), is performed. Then, development is performed using an alkali developer solution (manufactured by Tokyo Ohka Kogyo Co. Ltd., trade mark: NMD3). Thereby, resist pattern 1a having space T1 as shown in FIG. 5 is obtained.

### EXAMPLE 2

The resist material in the present example is a chemically amplified excimer resist manufactured by Tokyo Ohka Kogyo Co. Ltd.

First, a resist material is dropped onto insulating layer 2 as a material to be etched and rotationally applied on insulating layer 2. Thereby, as shown in FIG. 4, resist film 1 of film thickness of about 0.8 μm is formed on insulating film 2. Next, resist film 1 is pre-baked at temperature of 90° C. for 90 seconds and the solvent in resist film 1 is vaporized. Next, resist film 1 is exposed using a KrF excimer reduction projection exposure apparatus and a photo mask corresponding to the resist mask of the pattern as shown in FIG. 1 to FIG. 3. Next, a heat treatment at a temperature of 100° C. for 90 seconds after the exposure (PEB treatment) on resist film 1 is performed. Then, development is performed using an alkali developer solution (manufactured by Tokyo Ohka Kogyo Co. Ltd., trade mark: NMD-W). Thereby, resist pattern 1a having space T1 as shown in FIG. 5 is obtained.

### EXAMPLE 3

The resist material in the present example is a chemically amplified excimer resist manufactured by Tokyo Ohka Kogyo Co. Ltd.

First, a resist material is dropped onto insulating layer 2 as a material to be etched and rotationally applied on insulating layer 2, Thereby, as shown in FIG. 4, resist film 1 of film thickness of about 0.3 μm is formed. Next, a pre-bake of resist film 1 is performed at a temperature of 100° C. for 90 seconds. Thereby, the solvent in resist film 1 is vaporized. Then, resist film 1 is exposed using a KrF excimer reduction projection exposure apparatus and a photo mask corresponding to the resist pattern as shown in FIG. 1 to FIG. 3. Next, a heat treatment at a temperature of 100° C. for 90 seconds after the exposure (PEB treatment) is performed. Next, development is performed using an alkali developer solution (manufactured by Tokyo Ohka Kogyo Co. Ltd., trade mark: NMD-3) and thereby, resist pattern 1a having space T1 as shown in FIG. 5 is obtained.

### EXAMPLE 4

The resist material in the present invention is a chemically amplified resist manufactured by Ryoden Kasei Co., Ltd. (MELKER, J. Vac. Sci. Technol., B 11 (6) 2773, 1993) including the tertiary butoxy carbonylation (t-Boc) of polyhydroxystyrene and an acid generating agent.

First, a resist material is dropped onto insulating layer 2 as a material to be etched and rotationally applied on insulating layer 2. Thereby, as shown in FIG. 4, resist film 1 of film thickness of about 0.52 μm is formed. Next, a heat treatment of resist film 1 is performed at a temperature of 120° C. for 180 seconds and the solvent in resist film 1 is vaporized. Then, Espacer manufactured by Showa Denko KK (ESP100 (R)) as a charge-dissipating agent for electron beam lithography is rotationally applied onto resist film 1.

Next, a heat treatment of resist film 1 is performed at a temperature of 80° C. for 120 seconds. Next, electronic beam lithography is performed at an output power of 17.4 μC/cm² using an EB (electron beam) lithography apparatus. Next, a heat treatment after exposure (PEB treatment) is performed at a temperature of 80° C. for 120 seconds. Then, an antistatic film is removed using pure water. Next, development is performed using a tetramethylammonium hydroxide (TMAH) alkali developer solution (manufactured by Tokyo Ohka Kogyo Co. Ltd., trade mark: NMND-W). Thereby, resist pattern 1a having space T1 as shown in FIG. 5 is obtained.

Next, in Examples 5 and 6, a method of forming a raw material of a cover layer as a material for forming a fine pattern in the present invention is explained.

### EXAMPLE 5

In the present example, a copolymer of acrylic acid and vinylpyrrolidone (acrylic acid:vinylprrolidone=75:25 (weight ratio)) and triethanolamine are mixed at weight ratio of 10:1, and a solution having a concentration of 10 wt % of the entire solid component as a raw material of cover layer 3 is prepared.

Furthermore, in the case that a resist having a high hydrophobicity represented by an ArF resist is used, lower alcohol, a mixed solution of lower alcohol and water, or a mixed solution of lower alcohol and a non-polar solvent may be used besides water. The lower alcohol is an alcohol having 5 carbon atoms or less.

Further, it is desired that the raw material of cover layer 3 is formed by adding a surfactant of 100 ppm to the above-described solution. When a surfactant is added, uniformity of resist material and easiness of the application are improved. Further, an example of the surfactant used is a surfactant including octylpyrrolidone or polyethylene oxide.

### EXAMPLE 6

In the present example, acrylic acid and metacrylamide are mixed at weight ratio of 8:2, and a solution having a concentration of 10 wt % of the entire solid component as a raw material of cover layer 3 is prepared. A surfactant of 100 ppm is added to this solution. Furthermore, the same surfactant as in Example 5 is used.

Next, in Examples 7 to 11, a material for forming a fine pattern and a method of forming a fine pattern are explained.

### EXAMPLE 7

In the method of forming a fine pattern in the present invention, first, as shown in FIG. 5, resist pattern 1a explained in Example 2 is formed on insulation layer 2. Next, a raw material of cover layer 3 explained in Example 6 is dropped onto insulating layer 2 as to cover resist pattern 1a and is spin-coated onto insulating layer 2. Then, a pre-bake of the raw material of cover layer 3 is performed at a temperature of 85° C. for 70 seconds. Thereby, as shown in FIG. 6, cover layer 3 covering resist pattern 1a is formed. The raw material of cover layer 3 is the material for forming a fine pattern in the present invention. Then, a mixing bake (MB) is performed at a temperature of 105° C. for 70 seconds. Thereby, as shown in FIG. 7, a component in cover layer 3 permeates into resist pattern 1a, and mixed layer 4 is formed.

Next, development and peeling are performed using pure water, and thereby, as shown in FIG. 8, cover layer 3 is removed. Then, as shown in FIG. 9, a post-bake of mixed layer 4 is performed at a temperature of 130° C., which is lower than the softening point of resist pattern 1a and higher than that of mixed layer 4, for 60 seconds. Thereby, only mixed layer 4 is softened while resist pattern 1a is not softened. As a result, as shown in FIG. 9, resist pattern 1a is formed with mixed layer 4a having a larger thickness than the thickness of mixed layer 4 in the direction parallel to the main surface of insulating layer 2. That is, space t of resist pattern 1a with mixed layer 4a shown in FIG. 9 is smaller than space T2 of resist pattern 1a with mixed layer 4 shown in FIG. 8.

In the method of forming a fine pattern in the present example, only mixed layer 4 is softened while resist pattern 1a is not softened. Because control to change the external shape of such resist pattern is relatively easy, it is possible to make the space of resist patterns small uniformly, not depending on the form of the resist pattern.

Further, when a hole pattern as a fine pattern, a line pattern, and a space pattern are formed using resist pattern 1a with mixed layer 4a as the above-described material for forming a fine pattern as an etching mask, a pattern which is finer than the conventional pattern can be formed.

Furthermore, the dimension of space T1 of resist pattern 1a and the dimension of space t of the fine pattern formed with a method of forming a fine pattern in the present example are shown in Table 1. Each dimension of a hole pattern shown in FIG. 1, a line pattern shown in FIG. 2, and a space pattern shown in FIG. 3 is described in Table 1.

TABLE 1

| | Hole | Line | Space |
|---|---|---|---|
| | Pattern | Pattern | Pattern |
| Dimension of Space T1 of Resist | 200 | 200 | 200 |
| Pattern | | | |
| Dimension of Space t of Fine | 170 | 170 | 175 |
| Pattern in The Present Example | | | |

### EXAMPLE 8

In the method of forming a fine pattern in the present invention, first, as shown in FIG. 5, resist pattern 1a explained in Example 3 is formed on insulation layer 2. Next, a raw material of cover layer 3 explained in Example 5, that is a material for forming a fine pattern, is dropped onto insulating layer 2 as to cover resist pattern 1a and is spin-coated onto insulating layer 2.

Then, a pre-bake of the raw material of cover layer 3 is performed at a temperature of 85° C. for 70 seconds. Thereby, as shown in FIG. 6, cover layer 3 covering resist pattern 1a is formed, Next, a mixing bake (MB) is performed at a temperature of 155° C., which is lower than the softening point of resist pattern 1a and higher than that of the mixed layer formed by a component in cover layer 3 permeating into resist pattern 1a, for 90 seconds. More specifically, only the mixed layer formed by a component in cover layer 3 permeating into resist pattern 1 is softened while resist pattern 1a is not softened.

Thereby, as shown in FIG. 11, mixed layer 4a is formed having a larger thickness in the direction parallel to the surface of insulating layer 2 compared to the mixed layer right after it was formed by a component in cover layer 3 permeating into resist pattern 1. In such a manner, in the present example, a heat treatment for forming the mixed layer formed by a component in cover layer 3 permeating into resist pattern 1 and a heat treatment for forming mixed layer 4a by softening the mixed layer after the first heat treatment are performed in a series of heat treatments. Thereby, resist pattern 1a with mixed layer 4a is formed and space t is smaller than space T2 of resist pattern 1a with the mixed layer right after it was formed by a component in cover layer 3 permeating into resist pattern 1.

Furthermore, the component permeating into resist pattern 1a from cover layer 3 is, for example, triethanolamine as a low molecular weight amine in cover layer 3. By changing basicity, molecular weight, and content of the amine species, the thickness of the mixed layer right after it was formed by a component in cover layer 3 permeating into resist pattern 1 and its softening point can be adjusted. Next, development and peeling are performed using pure water, and thereby, as shown in FIG. 9, cover layer 3 is removed. As a result, resist pattern 1a with mixed layer 4a is exposed.

In the method of forming a fine pattern in the present example, only the mixed layer formed by a component in cover layer 3 permeating into resist pattern 1 is softened while resist pattern 1a is not softened.

Furthermore, the dimension of space T1 of resist pattern 1a and the dimension of space t of the fine pattern formed with the method of forming a fine pattern in the present example are shown in Table 2. Each dimension of a hole pattern shown in FIG. 1, a line pattern shown in FIG. 2, and a space pattern shown in FIG. 3 is described as well in Table 2.

TABLE 2

| | Hole | Line | Space |
|---|---|---|---|
| | Pattern | Pattern | Pattern |
| Dimension of Space T1 of Resist | 160 | 160 | 160 |
| Pattern | | | |
| Dimension of Space t of Fine | 130 | 126 | 120 |
| Pattern in The Present Example | | | |

### EXAMPLE 9

In the method of forming a fine pattern in the present invention, first, as shown in FIG. 5, resist pattern 1a explained in Example 3 is formed on insulation layer 2. Next, a raw material of cover layer 3 as a material for forming a fine pattern in the present invention explained in Example 5 is dropped onto insulating layer 2 as to cover resist pattern 1a and is spin-coated onto insulating layer 2. Then, a pre-bake of the raw material of cover layer 3 is performed at a temperature of 85° C. for 70 seconds, and as shown in FIG. 6, cover layer 3 covering resist pattern 1a is formed.

Next, a mixing bake (MB) is performed at a temperature of 105° C. for 70 seconds, and as shown in FIG. 7, mixed layer 4 is formed by a component in cover layer 3 permeating into resist pattern 1a. Next, development and peeling is performed using pure water, and thereby, as shown in FIG. 8, cover layer 3 is removed.

Then, a post-bake of mixed layer 4 is performed at a temperature of 155° C., which is lower than the softening point of resist pattern 1a and higher than that of mixed layer 4, for 60 seconds. Thereby, as shown in FIG. 9, only mixed layer 4 is softened while resist pattern 1a is not softened, and mixed layer 4a is formed having a larger width than that of mixed layer 4 in the direction parallel to the main surface of insulating layer 2. That is, resist pattern 1a with mixed layer 4a having a smaller space t than space T2 of resist pattern 1a with mixed layer 4 is formed.

In the method of forming a fine pattern in the present example, only the mixed layer 4 is softened while resist pattern 1a is not softened.

Furthermore, the dimension of space T1 of resist pattern 1a and the dimension of space t of the fine pattern formed with a method of forming a fine pattern in the present example are shown in Table 3. Each dimension of a hole pattern shown in FIG. 1, a line pattern shown in FIG. 2, and a space pattern shown in FIG. 3 is described as well in Table 3.

TABLE 3

| | Hole | Line | Space |
|---|---|---|---|
| | Pattern | Pattern | Pattern |
| Dimension of Space T1 of Resist | 160 | 160 | 160 |
| Pattern | | | |
| Dimension of Space t of Fine | 140 | 136 | 130 |
| Pattern in The Present Example | | | |

### EXAMPLE 10

In the method of forming a fine pattern in the present invention, first, as shown in FIG. 5, resist pattern 1a explained in Example 1 is formed on insulation layer 2. Next, a raw material of cover layer 3 as a material for forming a fine pattern in the present invention explained in Example 6 is dropped onto insulating layer 2 as to cover resist pattern 1a and is spin-coated onto insulating layer 2. Then, a pre-bake of resist pattern 1a is performed at a temperature of 85° C. for 70 seconds.

Next, in the state shown in FIG. 6, cover layer 3 and resist pattern 1a are pre-baked (MB) at a temperature of 105° C. for 70 seconds. Thereby, a component in cover layer 3 permeates into resist pattern 1a and mixed layer 4 is formed as shown in FIG. 7. Next, development and peeling is performed using pure water, and thereby, as shown in FIG. 8, cover layer 3 is removed.

Then, a heat treatment after exposure (PEB treatment) of resist pattern 1a is performed at a temperature of 130° C., which is lower than the softening point of resist pattern 1a and higher than that of mixed layer 4, for 60 seconds. Thereby, only mixed layer 4 is softened while resist pattern 1a is not softened. As a result, as shown in FIG. 9, mixed layer 4a is formed having a larger thickness than that of mixed layer 4 in the direction parallel to the main surface of insulating layer 2. That is, space t of resist pattern 1a with mixed layer 4a is smaller than space T2 of resist pattern 1a with mixed layer 4.

Also in the method of forming a fine pattern in the present example, only the mixed layer 4 is softened while resist pattern 1a is not softened.

Furthermore, the dimension of space T1 of resist pattern 1a and the dimension of space t of the fine pattern formed with a method of forming a fine pattern in the present example are shown in Table 4. Each dimension of a hole pattern shown in FIG. 1, a line pattern shown in FIG. 2, and a space pattern shown in FIG. 3 is described as well in Table 4.

TABLE 4

| | Hole | Line | Space |
|---|---|---|---|
| | Pattern | Pattern | Pattern |
| Dimension of Space T1 of Resist | 400 | 410 | 410 |
| Pattern | | | |
| Dimension of Space t of Fine | 370 | 380 | 380 |
| Pattern in The Present Example | | | |

### EXAMPLE 11

In the method of forming a fine pattern in the present invention, first, as shown in FIG. 5, resist pattern 1a explained in Example 4 is formed on insulation layer 2. Next, a raw material of cover layer 3 as a material for forming a fine pattern in the present invention explained in Example 5 is dropped onto insulating layer 2 as to cover resist pattern 1a and is spin-coated onto insulating layer 2.

Then, the raw material of cover layer 3 is pre-baked at a temperature of 85° C. for 70 seconds. Thereby, as shown in FIG. 6, cover layer 3 covering resist pattern 1a is formed. Further, a mixing bake (MB) is performed at a temperature of 135° C., which is lower than the softening point of resist pattern 1a and higher than that of mixed layer formed by a component in cover layer 3 permeating into resist pattern 1a, for 90 seconds. That is, a heat treatment for forming the mixed layer right after a component in cover layer 3 permeates into resist pattern 1a and a heat treatment for softening the mixed layer after the first heat treatment are performed in a series of heat treatment.

Thereby, as shown in FIG. 11, mixed layer 4a is formed between resist pattern 1a and cover layer 3. The thickness of mixed layer 4a is larger than that of mixed layer right after it was formed by a component in cover layer 3 permeating into resist pattern 1a. That is, space t of resist pattern 1a with mixed layer 4a is smaller than space T2 of resist pattern 1a with the mixed pattern right after it was formed by a component in cover layer 3 permeating into resist pattern 1a. Next, development and peeling is performed using pure water, and thereby, cover layer 3 is removed as shown in FIG. 9.

Also in the method of forming a fine pattern in the present example, only the mixed layer is softened while the first resist pattern 1a is not softened.

Furthermore, the dimension of space T1 of resist pattern 1a and the dimension of space t of the fine pattern formed with a method of forming a fine pattern in the present example are shown in Table 5. Each dimension of a hole pattern shown in FIG. 1, a line pattern shown in FIG. 2, and a space pattern shown in FIG. 3 is described as well in Table 5.

TABLE 5

| | Hole | Line | Space |
|---|---|---|---|
| | Pattern | Pattern | Pattern |
| Dimension of Space T1 of Resist | 200 | 200 | 200 |
| Pattern | | | |
| Dimension of Space t of Fine | 170 | 170 | 170 |
| Pattern in The Present Example | | | |

The method of forming a fine pattern described in each of the above examples can be applied to a manufacturing process of a semiconductor device, a manufacturing process of a magnetic head, and a manufacturing process of a micro-lens, and preferably applied to a manufacturing process of a semiconductor device such as SOC (System On Chip) especially.

Further, the method of forming a fine pattern in the present invention is not limited to the method of forming a fine pattern in the embodiment explained in Examples 7 to 11, and can be applied to methods of forming fine patterns in various manners. Especially, the method of forming a fine pattern in the present invention is preferably used for forming a contact hole pattern connecting a substrate of a semiconductor device and wiring and a via-hole pattern connecting under layer wiring and upper layer wiring.

Further, various materials can be used as a material of the above-described insulating layer 2, and materials such as TEOS (Tetra Ethyl Ortho Silicate Glass) and materials with a low dielectric constant (Low-k) are desirably used.

Furthermore, besides the raw materials of cover layer 3 as the material for forming a fine pattern in the present invention shown in the above-described examples, the materials shown in the next Table 6 and Table 7 can be used as a raw material of cover layer 3. The raw material of cover layer 3 includes a solvent, a resin dissolving into the solvent, and an additive. Furthermore, combinations of the raw material of cover layer 3 when a water-soluble solvent is used are described in Table 6, and combinations of the raw material of cover layer 3 when a water-insoluble solvent is used are described in Table 7.

TABLE 6

| | | | ADDITIVE (LOW MOLECULAR WEIGHT AND |
|---|---|---|---|
| EXPOSURE LIGHT SOURCE | SOLVENT | RESIN | PERMEABLE SOLVENT) |
| i-line | (Water-soluble) | Polyacrylic acid | (Amine) |
| KrF | Water | Polyacrylic acid amide | Monoethanolamine |
| EUV | Water and Alcohol (up to | Polyvinylacetal | Diethanolamine |
| EB | α %) | Polyvinylpyrrolidone | Triethanolamine |
| (Resist having phenolic | Alcohol = in which a | Polyvinyl alcohol | Diaminopropane |
| resins such as novolak or | backing resist does not | Polyethyleneimine | N(CH₂CH₂NH₂)₃ |
| polyhydoxystyrene as the | dissolve | Polyethylene oxide | Polyethyleneimine oligomer |
| main component) | Ethanol | Polymethacrylic acid | Polyallylamine oligomer |
| The above-mentioned | Propanol (n-, iso-) | Polymethacrylic acid amide | (Amide) |
| materials have α = 10%. | Butanol (n-, iso-, tert-) | Styrene-maleic acid copolymer | Acrylic acid amide |
| ArF resist | Mixtures of two kinds or | Polyvinylamine resin | Methacrylic acid amide |
| Resist having high | more of the above- | Polyallylamine | Sulfonic acid amide |
| hydrophobicity and having a | mentioned alcohols | Oxazoline group-containing | Mixtures of two kinds or more of |
| blocking body of acrylic or | Ketone-based solvent | water-soluble resin | the above-mentioned low molecular |
| polycycloolefin polymers as | (Alkylketone) | Water-soluble melamine resin | weight components |
| the main component | | Water-soluble urea resin | (Permeable solvent) |
| The above-mentioned | | Alkyd resin | N-methyl-pyrrolidone (NMP) |
| materials have α = 30%. | | Sulfonamide resin | Dimethylsulfooxide (DMSO) |
| | | Ethylene glycol | Dimethylacetamide (DMAc) |
| | | Mixtures of two kinds or more | Dimethylformamide (DMF) |
| | | of the above-mentioned resins | Tetrahydrofuran (THF) |
| | | Copolymers of two kinds or more | Mixtures of two kind or more of the |
| | | of the above-mentioned resins | above-mentioned permeable solvent |

TABLE 7

| | | | ADDITIVE (LOW MOLECULAR WEIGHT AND |
|---|---|---|---|
| EXPOSURE LIGHT SOURCE | SOLVENT | RESIN | PERMEABLE SOLVENT) |
| i-line | (Water-insoluble) | Polyacrylic ester | (Amine) |
| KrF | Xylene | Polyacrylic acid amide | Monoethanolamine |
| EUV | Toluene | Polyvinylacetal | Diethanolamine |
| EB | Anisol | Polyvinyl ether | Triethanolamine |
| (Resist having phenolic | Cyclohexane | Polystyrene | Diaminopropane |
| resins such as novolak or | Cyclohexanol | Polycarbonate | N(CH₂CH₂NH₂)₃ |
| polyhydoxystyrene as the | Mixtures of two kinds or | Polyethyleneimine | Polyethyleneimine oligomer |
| main component) | more of the | Polyethylene oxide | Polyallylamine oligomer |
| The above-mentioned | above-mentioned | Polymethacrylic acid ester | (Amide) |
| materials have α = 10%. | water-insoluble solvent | Polymethacrylic acid amide | Acrylic acid amide |
| ArF resist | Ketone-based solvent | Polyvinylamine resin | Methacrylic acid amide |
| Resist having high | (Alkylketone) | Polyallylamine | Sulfonic acid amide |
| hydrophobicity and having a | | Oxazoline group-containing | Mixtures of two kinds or more of |
| blocking body of acrylic or | | water-soluble resin | the above-mentioned low molecular |
| polycycloolefin polymers as | | Melamine resin | weight components |
| the main component | | Urea resin | (Permeable solvent) |
| The above-mentioned | | Alkyd resin | N-methyl-pyrrolidone (NMP) |
| materials have α = 30%. | | Sulfonamide resin | Dimethylsulfooxide (DMSO) |
| | | Fluororesin | Dimethylacetamide (DMAc) |
| | | Polyester resin | Dimethylformamide (DMF) |
| | | Polyamide resin | Tetrahydrofuran (THF) |
| | | Alkoxycellulose | Mixtures of two kind or more of the |
| | | Mixtures of two kinds or more | above-mentioned permeable solvent |
| | | of the above-mentioned resins | |
| | | Copolymers of two kinds or more | |
| | | of the above-mentioned resins | |

Furthermore, as shown in Table 6 and Table 7, any one of i-line, KrF, EUV (Extreme Ultra Violet), and EB (Electron Beam) can be used as an exposure light source. Further, a resist having phenolic resins such as novolak or polyhydoxystyrene as the main component can be used as a resist material. In this case, when an alcohol solution is used as a solvent, the content ratio α of the alcohol is 10% or less. Further, a resist having high hydrophobicity and having a blocking body (Blocking Group) of ArF resist acrylic or polycycloolefin polymers as the main component may be used as a resist material. In this case, when an alcohol solution is used as a solvent, the content ratio α of the alcohol is 30% or less.

Further, as shown in Table 6, water or water and lower alcohol (up to α%) is used as a water-soluble solvent. A backing resist does not dissolve into lower alcohol. Any one of ethanol, propanol (n-, iso-), and butanol (n-, iso-, tert-) can be used as the lower alcohol. However, mixtures of two kinds or more of their alcohols may be used as a water-soluble solvent. Moreover, ketone-based solvent, for example alkylketone, may be used as a solvent. The resist pattern does not dissolve into these solvents.

Further, any one of polyacrylic acid, polyacrylic acid amide, polyvinylacetal, polyvinylpyrrolidone, polyvinyl alcohol, polyethyleneimine, polyethylene oxide, polymethacrylic acid, polymethacrylic acid amide, a styrene-maleic acid copolymer, a polyvinylamine resin, polyallylamine, an oxazoline group-containing water-soluble resin, a water-soluble melamine resin, a water-soluble urea resin, an alkyd resin, a sulfonamide resin, ethylene glycol, mixtures of two kinds or more of the above-described resins, and copolymers of two kinds or more of the above-described resins may be used as a resin mixed into the above-described water-soluble solvent.

Further, any one of low molecular weight amine compounds: monoethanolamine, diethanolamine, triethanolamine, diaminopropane, N(CH₂CH₂NH₂)₃, a polyethyleneimine oligomer, and a polyallylamine oligomer may be used as the additive added to the water-soluble solvent as a permeable component. Further, any one of low molecular weight amide compounds: acrylic acid amide, methacrylic acid amide, and sulfonic acid amide may be used as the additive added to the water-soluble solvent. Further, mixtures of two kinds or more of the above-described low molecular weight amine compounds and low molecular weight amide compounds may be used. Furthermore, in the above-described case, low molecular weight means a molecule consisting of monomers or oligomers, and having a molecular weight of 500 or less.

Further, a permeable solvent having a lone pair may be used as the additive added to the water-soluble solvent. The permeable solvent has the character to function as a donor supplying electrons because it has a lone pair. Any one of N-methyl-pyrrolidone (NMP), dimethylsulfooxide (DMSO), dimethylacetamide (DMAc), dimethylformamide (DMF), and tetrahydrofuran (THF) may be used as the permeable solvent. Further, mixtures of two kinds or more of these permeable solvents may be used.

Further, as shown in Table 7, any one of xylene, toluene, anisol, cyclohexane, cyclohexanol, and mixtures of two kinds or more of these water-insoluble solvents may be used as the water-insoluble solvent. Moreover, ketone-based solvent, for example alkylketone, may be used as the water-insoluble solvent.

Further, polyacrylic ester, polyacrylic acid amide, polyvinylacetal, polyvinyl ether, polystyrene, polycarbonate, polyethyleneimine, polyethylene oxide, polymethacrylic acid ester, polymethacrylic acid amide, polyvinylamine resin, a polyallylamine oxazoline group-containing water-soluble resin, a melamine resin, an urea resin, an alkyd resin, a sulfonamide resin, a fluororesin, a polyester resin, a polyamide resin, alkoxycellulose, mixtures of two kinds or more of the above-described resins, and copolymers of two kinds or more of the above-described resins can be used as the resin mixed into the above-described water-insoluble solvent.

Further, any one of low molecular weight amine compounds: monoethanolamine, diethanolamine, triethanolamine, diaminopropane, N(CH₂CH₂NH₂)₃, a polyethyleneimine oligomer, and a polyallylamine oligomer may be used as the additive added to the water-insoluble solvent. Further, any one of low molecular weight amide compounds: acrylic acid amide, methacrylic acid amide, and sulfonic acid amide may be used as the additive added to the water-insoluble solvent. Further, mixtures of two kinds or more of the above-described low molecular weight amine compounds and low molecular weight amide compounds may be used. Furthermore, low molecular weight means a molecule consisting of monomers or oligomers, and having a molecular weight of 500 or less.

Further, a permeable solvent having a lone pair may be used as the additive added to the water-insoluble solvent. The permeable solvent has the character to function as a donor supplying electrons because it has a lone pair as described above. Any one of N-methyl-pyrrolidone (NMP), dimethylsulfooxide (DMSO), dimethylacetamide (DMAc), dimethylformamide (DMF), and tetrahydrofuran (THF) may be used as the permeable solvent. Further, mixtures of two kinds or more of these permeable solvents may be used.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A material for forming a fine pattern to be applied on a resist pattern as a cover layer covering said resist pattern on a substrate, wherein
a mixed layer is formed having a lower softening point than a softening point of said resist pattern by the component permeating into said resist pattern, and
said mixed layer is then softened by performing a heat treatment at a temperature lower than the softening point of said resist pattern and higher than the softening point of said mixed layer, and a space of said resist pattern is narrowed.

2. The material for forming a fine pattern according to claim 1, wherein a material having a resin dissolving into a solvent in which said resist pattern does not dissolve is a main component.

3. The material for forming a fine pattern according to claim 2, wherein at least one kind of material selected from alkylene glycol polymers, cellulose derivatives, vinyl derivatives, acrylic derivatives, urea polymers, epoxy polymers, melamine polymers, nylon polymers, and styrene polymers is used as said resin.

4. The material for forming a fine pattern according to claim 2, wherein a monomer or an oligomer of amine compounds, or a monomer or an oligomer of amide compounds may be added to said solvent.

5. The material for forming a fine pattern according to claim 2, wherein a permeable solvent having a lone pair is added to said solvent.

6. The material for forming a fine pattern according to claim 2, wherein a surfactant is added to said solvent.

7. A method of forming a fine pattern comprising the steps of:
forming a resist pattern on a substrate;
forming a cover layer covering said resist pattern;
forming a mixed layer having a lower softening point than a softening point of said resist pattern by a component in said cover layer permeating into said resist pattern;
softening said mixed layer by performing a heat treatment at a temperature lower than the softening point of said resist pattern and higher than the softening point of said mixed layer, and narrowing a space of said resist pattern; and
removing said cover layer.

8. The method of forming a fine pattern according to claim 7, wherein said forming the mixed layer and said softening the mixed layer are performed in two kinds of heat treatment steps with different treatment conditions.

9. The method of forming a fine pattern according to claim 7, wherein said forming the mixed layer and said softening the mixed layer are performed in a series of heat treatment steps of the same treatment condition.

10. The method of forming a fine pattern according to claim 7, wherein said heat treatment for softening the mixed layer is performed after said removing the cover layer.

11. The method of forming a fine pattern according to claim 7, wherein said heat treatment for softening the mixed layer is performed before said removing the cover layer.

12. A method of manufacturing an electronic device comprising the steps of:
forming a resist pattern on a material to be etched formed on a substrate;
forming a cover layer covering said resist pattern;
forming a mixed layer having a lower softening point than a softening point of said resist pattern by a component in said cover layer permeating into said resist pattern;
softening said mixed layer by performing a heat treatment at a temperature lower than the softening point of said resist pattern and higher than the softening point of said mixed layer and narrowing space of said resist pattern;
removing said cover layer; and
etching said material to be etched using said resist pattern having said mixed layer after softening as a mask.

13. An electronic device manufactured with the method of manufacturing an electronic device of claim 12.
